(19) United States
(12) Patent Application Publication
(10) Pub. No.: US 2014/0002970 A1
(43) Pub. Date: Jan. 2, 2014

(54) SLIDABLE CONNECTING DEVICE AND ELECTRONIC DEVICE USING THE SAME

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventor: ZHI-YONG REN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/693,043

(22) Filed: Dec. 4, 2012

(30) Foreign Application Priority Data
Jun. 29, 2012 (CN) 201210220704.0

(51) Int. Cl. H05K 7/14

(52) U.S. Cl. CPC H05K 7/14
USPC 361/679.01; 384/26

(57) ABSTRACT

An electronic device includes a main body, a grip, and a slidable connecting device for connecting the grip to the main body. The slidable connecting device includes a flat block connected to the grip, a resilient loop arranged around a periphery of the flat block, and a sliding member comprising a first end securely coupled to the main body and a second end slidably connected to the flat block. The sliding member further includes a tab that is arranged between the periphery and the resilient loop and is used to tension the resilient loop, enabling the resilient loop to be able to apply a force to the tab, thereby allowing the sliding member to be positioned at a desired position by the force.

### BACKGROUND

1. Technical Field

The present disclosure relates to a slidable connecting device.

2. Description of Related Art

Slidable connecting mechanisms for slidably connecting two parts of electronic devices are known. For example, many slide cell phones include a base and a display that are slidably connected to each other by such connecting mechanisms. Although some slidable connecting mechanisms can satisfy basic requirements, it is still useful to provide a new slidable connecting device.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device in accordance with an exemplary embodiment.

FIG. 2 is an isometric exploded view of a connecting device of the electronic device of FIG. 1.

FIG. 3 is similar to FIG. 2, but viewed in another viewpoint.

FIG. 4 is cross-sectional view of the connecting device of the electronic device of FIG. 1.

### DETAILED DESCRIPTION

Embodiments of the present disclosure will be described with reference to the accompanying drawings.

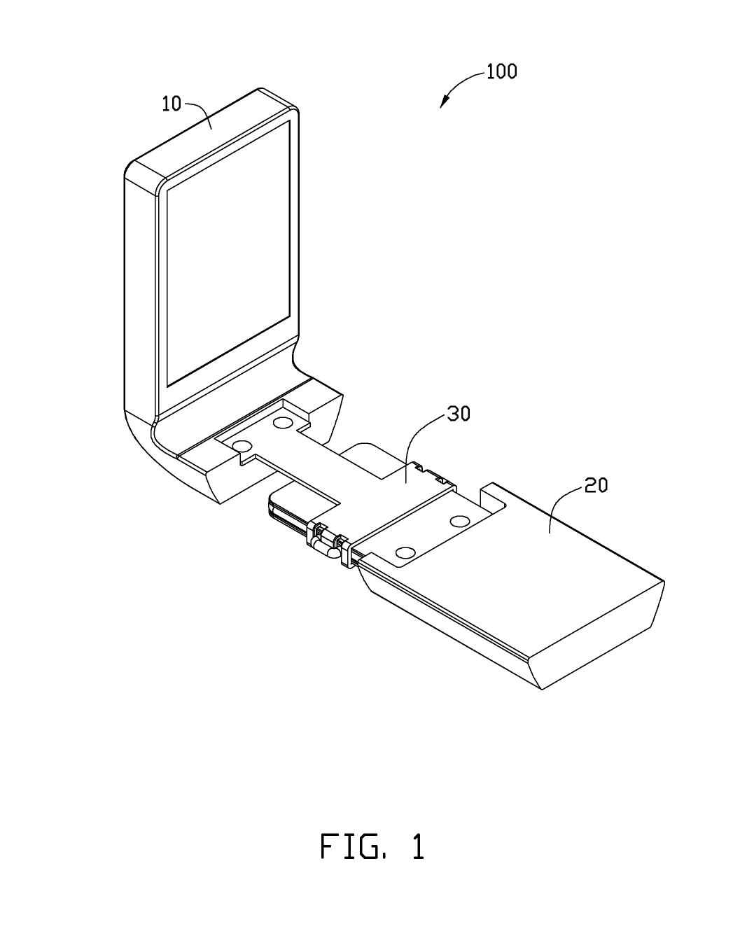

Referring to FIG. 1, an electronic device 100 includes a main body 10 and a grip 20 that are connected to each other by a slidable connecting device 30. The connecting device 30 allows the main body 30 and the grip 20 to move with respect to one another. In the embodiment, the electronic device 100 is a digital camera.

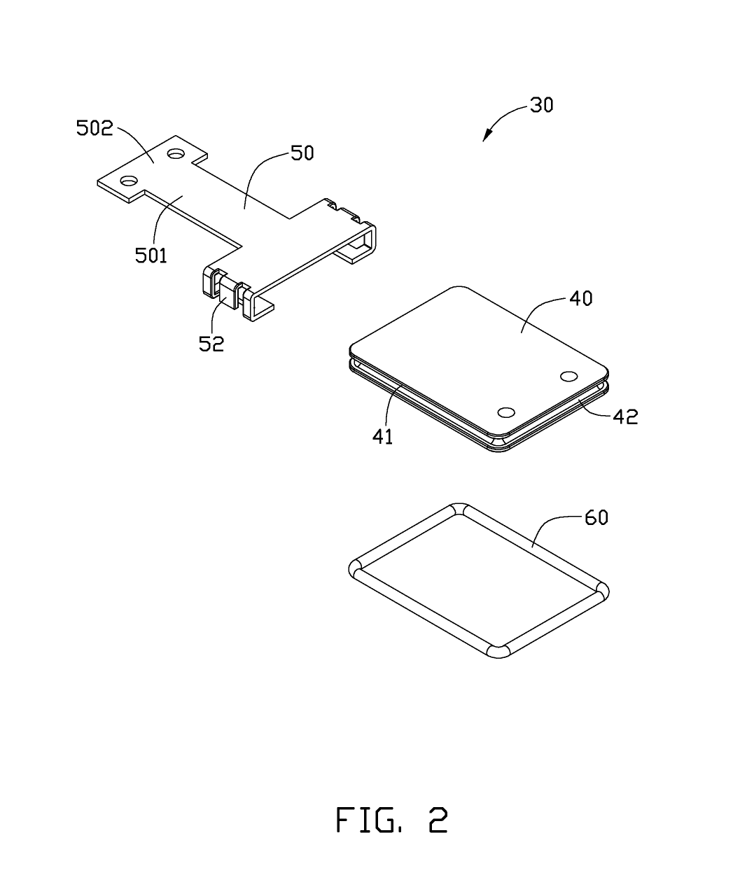

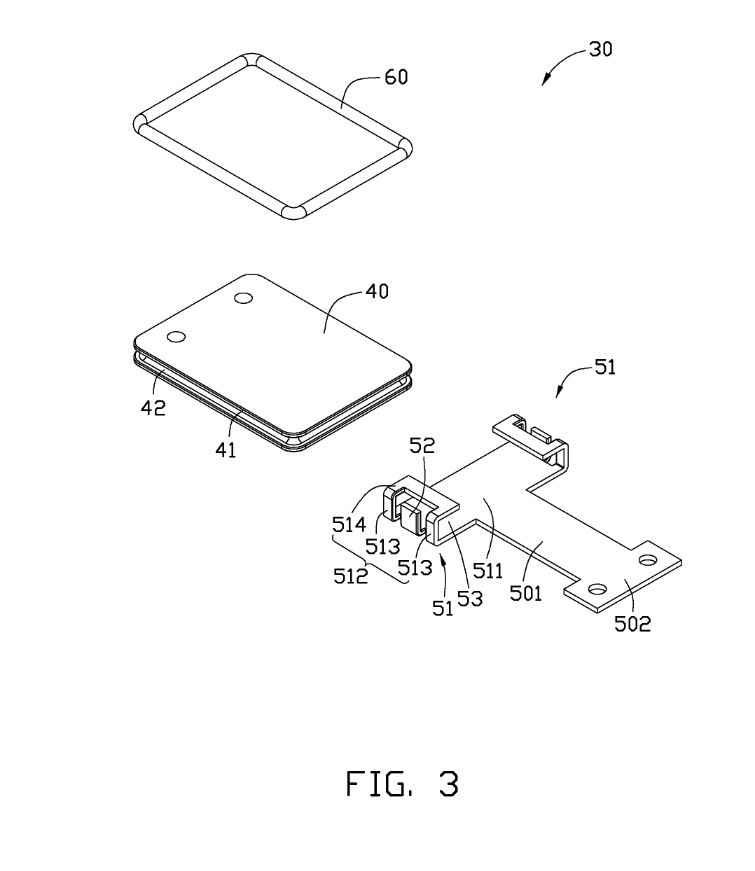

Referring to FIGS. 2 and 3, the connecting device 30 includes a plate-shaped block 40, a sliding member 50, and a resilient loop 60 wrapped around a periphery 41 of the plate-shaped block 40. The plate-shaped block 40 is securely coupled to the grip 20, and defines a groove 42 in the periphery 41. The resilient loop 60 is received in the groove 42. In the embodiment, the resilient loop 60 is made of nylon.

The sliding member 50 includes a flat sheet 501 having a first end portion 502 securely coupled to the main body 10. The flat sheet 501 further includes a second end portion 51 clamping the plate-shaped block 40. The second end portion 51 includes a flat portion 511 and two angled portion 512 protruding from opposite ends of the flat portion 511. The flat portion 511 and the angled portions 512 cooperatively define a sliding groove 53. The plate-shaped block 40 is slidable in the sliding groove 53.

In the embodiment, each angled portions 512 includes two spaced vertical walls 513 protruding from one end of the flat portion 511 and two horizontal portions 514 respectively protruding from ends of the vertical walls 513. A tab 52 protrudes from one end of the flat portion 511 and is arranged between two vertical walls 513 of one angled portion 512.

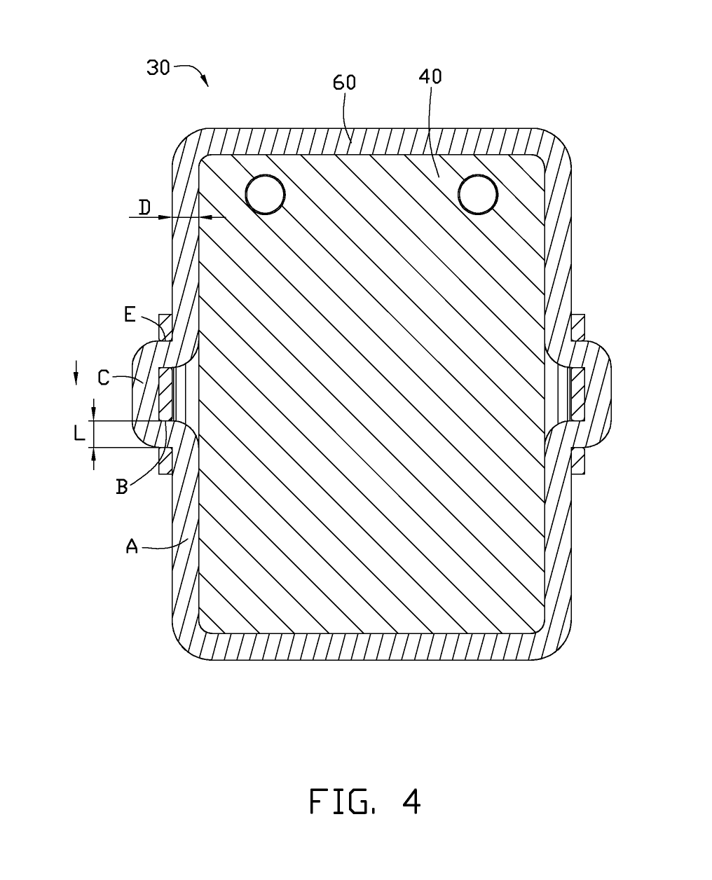

Referring to FIG. 4, the tab 52 is located between the loop 60 and the periphery 41, and is used to tension the loop 60, such that the loop 60 can press tightly against the tab 52, which can position the tab 52 in any desired position. The size L of the gap B and E between each vertical walls and the tab 52 is slightly smaller than the width D of the loop 60. When the sliding member 50 moves with respect to the plate-shaped block 40 along the direction indicated by the arrow in FIG. 4, a portion of the loop 60 passes through the gap B and then passes through the gap E. A resistance force is then applied to the loop 60, which facilitates a steady movement of the sliding member 50.

While various embodiments have been described and illustrated, the disclosure is not to be construed as being limited thereto. Various modifications can be made to the embodiments by those skilled in the art without departing from the true spirit and scope of the present disclosure as defined by the appended claims.

What is claimed is:

1. A slidable connecting device for connecting a first object to a second object, the slidable connecting device comprising:
a plate-shaped block configured for connection to the first object;
a loop wrapped around a periphery of the block; and
a sliding member comprising a first end configured to be securely coupled to the second object and a second clamping end clamping the block, the second clamping end being slidable relative to the block, the sliding member further comprising a tab, the tab being sandwiched between the periphery and the resilient loop and being configured to tension the loop, thereby enabling the tensioned loop to tightly contact the tab, whereby the sliding member can be retained at a desired position by way of a frictional force created between the loop and the tab.

2. The slidable connecting device according to claim 1, wherein the block defines a groove in the periphery, and the resilient loop is received in the groove.

3. The slidable connecting device according to claim 1, wherein the loop is made of nylon.

4. The slidable connecting device according to claim 1, wherein the second clamping end comprises a planar portion and two angled portions protruding from opposite ends of the planar portion, the planar portion and the two angled portions cooperatively define a sliding groove, the flat block is slidable in the sliding groove.

5. The slidable connecting device according to claim 4, wherein each angled portion comprises two spaced vertical walls protruding from one end of the planar portion, the tab is arranged between two vertical walls of one angled portion, the two vertical walls of the one angled portion abut on the loop.

6. An electronic device comprising:
a main body;
a grip; and
a slidable connecting device for connecting the grip to the main body, the slidable connecting device comprising:
a plate-shaped block configured for connection to the first object;
a loop wrapped around a periphery of the block; and
a sliding member comprising a first end configured to be securely coupled to the second object and a second clamping end clamping the block, the second clamping end being slidable relative to the block, the sliding member further comprising a tab, the tab being sandwiched between the periphery and the resilient loop and being configured to tension the loop, thereby enabling the tensioned loop to tightly contact the tab, whereby the sliding member can be retained at a desired position by way of a frictional force created between the loop and the tab.

7. The electronic device according to claim 6, wherein the block defines a groove in the periphery, and the resilient loop is received in the groove.

8. The electronic device according to claim 6, wherein the loop is made of nylon.

9. The electronic device according to claim 6, wherein the second clamping end comprises a planar portion and two angled portions protruding from opposite ends of the planar portion, the planar portion and the two angled portions cooperatively define a sliding groove, the flat block is slidable in the sliding groove.

10. The electronic device according to claim 9, wherein each angled portion comprises two spaced vertical walls protruding from one end of the planar portion, the tab is arranged between two vertical walls of one angled portion, the two vertical walls of the one angled portion abut on the loop.
